(19) United States
(12) Patent Application Publication
(10) Pub. No.: US 2025/0070048 A1
(43) Pub. Date: Feb. 27, 2025

(54) SEMICONDUCTOR PACKAGE

(71) Applicant: SAMSUNG ELECTRONICS CO., LTD., Suwon-si (KR)

(72) Inventors: Dawoon JUNG, Suwon-si (KR); Haseob SEONG, Suwon-si (KR)

(73) Assignee: SAMSUNG ELECTRONICS CO., LTD., Suwon-si (KR)

(21) Appl. No.: 18/675,699

(22) Filed: May 28, 2024

(30) Foreign Application Priority Data
Aug. 22, 2023 (KR) 10-2023-0110136

(51) Int. Cl. H01L 23/00; H01L 23/28; H01L 23/48; H01L 25/16; H10B 80/00

(52) U.S. Cl. CPC H01L 23/562; H01L 23/28; H01L 23/481; H01L 24/08; H01L 24/16; H01L 25/16; H10B 80/00; H01L 2224/08145; H01L 2224/16225; H01L 2225/06541

(57) ABSTRACT

A semiconductor package includes a first semiconductor chip including: a first semiconductor substrate having an first active surface and a first inactive surface opposite to the first active surface, and a plurality of first electrodes penetrating through the first semiconductor substrate; a plurality of second semiconductor chips, each of the plurality of second semiconductor chips comprising: a second semiconductor substrate having a second active surface and a second inactive surface opposite to the second active surface, and a plurality of second electrodes penetrating through the second semiconductor substrate, wherein the plurality of second semiconductor chips are stacked on the first semiconductor chip, the second active surfaces of the plurality of second semiconductor substrates face the first inactive surface of the first semiconductor substrate, and vertical heights of the plurality of second semiconductor chips are identical.

### CROSS-REFERENCE TO RELATED APPLICATION

This application is based on and claims priority under 35 U.S.C. § 119 to Korean Patent Application No. 10-2023-0110136, filed on Aug. 22, 2023, in the Korean Intellectual Property Office, the disclosure of which is incorporated by reference herein in its entirety.

### BACKGROUND

The disclosure relates to a semiconductor package, and more particularly, to a semiconductor package including stacked semiconductor chips.

Electronic apparatuses are becoming more compact and lightweight according to the rapid development of the electronics industry and users' increased demand. As electronic apparatuses become smaller and lighter, semiconductor packages are also becoming smaller and lighter. In addition, high reliability, high performance, and large capacity are required for the semiconductor packages. As these semiconductor packages have high performance and large capacity, power consumption of the semiconductor packages needs to increase. Accordingly, structures of the semiconductor packages become more important, in order to cope with the size/performance of the semiconductor packages and provide stable power supply to the semiconductor packages.

### SUMMARY

Provided is a semiconductor package including stacked semiconductor chips and having improved structural reliability.

According to an aspect of the disclosure, a semiconductor package includes: a first semiconductor chip including: a first semiconductor substrate having an first active surface and a first inactive surface opposite to the first active surface, and a plurality of first electrodes penetrating through the first semiconductor substrate; a plurality of second semiconductor chips, each of the plurality of second semiconductor chips including: a second semiconductor substrate having a second active surface and a second inactive surface opposite to the second active surface, and a plurality of second electrodes penetrating through the second semiconductor substrate and stacked on the first semiconductor chip, wherein the second active surfaces of the plurality of second semiconductor substrates face the first inactive surface of the first semiconductor substrate, and the plurality of second semiconductor chips have vertical heights that are equal to each other; a plurality of coupling pads between the first semiconductor chip and the plurality of second semiconductor chips, the plurality of coupling pads electrically connecting the plurality of first electrodes to the plurality of second electrodes; chip coupling insulating layers, each of the chip coupling insulating layers surrounding the plurality of coupling pads and provided between the first semiconductor chip and the plurality of second semiconductor chips; and a support dummy substrate stacked on the plurality of second semiconductor chips, the support dummy substrate including a first support insulating layer on a lower surface of the support dummy substrate, wherein an uppermost second semiconductor chip among the plurality of second semiconductor chips includes a plurality of chip pads on the second inactive surface of the second semiconductor substrate of the uppermost second semiconductor chip, the support dummy substrate includes a plurality of solder balls on the lower surface of the support dummy substrate, and the plurality of solder balls are bonded to the plurality of chip pads.

According to an aspect of the disclosure, a semiconductor package includes: a high bandwidth memory (HBM) controller die including: a first semiconductor substrate having a first active surface and a first inactive surface opposite to the first active surface, and a plurality of first electrodes at least partially penetrating through the first semiconductor substrate; a plurality of dynamic random access memory (DRAM) dies, each of the plurality of DRAM dies including: a second semiconductor substrate having a second active surface and a second inactive surface opposite to the second active surface, and a plurality of second electrodes penetrating through the second semiconductor substrate and stacked on the HBM controller die, wherein the second active surfaces of the plurality of second semiconductor substrates face the first inactive surface of the first semiconductor substrate, and the plurality of DRAM dies have vertical heights that are equal to each other; a plurality of coupling pads between the HBM controller die and the plurality of DRAM dies, the plurality of coupling pads electrically connecting the plurality of first electrodes to the plurality of second electrodes; chip coupling insulating layers, each of the chip coupling insulating layers surrounding the plurality of coupling pads and provided between the HBM controller die and the plurality of DRAM dies; at least one first support dummy substrate stacked on the plurality of DRAM dies; and a second support dummy substrate between the at least one first support dummy substrate and an uppermost DRAM die among the plurality of DRAM dies, wherein the second support dummy substrate includes a plurality of chip pads on an upper surface of the second support dummy substrate that faces the at least one first support dummy substrate, and the at least one first support dummy substrate includes a plurality of solder balls on a lower surface of the at least one first support dummy substrate that faces the second support dummy substrate, and the plurality of solder balls are bonded to the plurality of chip pads.

According to an aspect of the disclosure, a semiconductor package includes: a base redistribution layer including: a plurality of package redistribution line patterns, a plurality of package redistribution vias contacting and connected to at least one of the plurality of package redistribution line patterns, and a package redistribution insulating layer surrounding the plurality of package redistribution line patterns and the plurality of package redistribution vias; a high bandwidth memory (HBM) controller die including: a first semiconductor substrate having a first active surface and a first inactive surface opposite to the first active surface, and a plurality of first electrodes at least partially penetrating through the first semiconductor substrate, wherein the HBM controller die has a first horizontal width and a first vertical height; a plurality of dynamic random access memory (DRAM) dies, each of the plurality of DRAM dies including a second semiconductor substrate having a second active surface and a second inactive surface opposite to the second active surface, wherein the plurality of DRAM dies are stacked on the HBM controller die, the second active surfaces of the plurality of second semiconductor substrates face the first inactive surface of the first semiconductor substrate, and each of the plurality of DRAM dies has a second horizontal width that is less than the first horizontal width of the HBM controller die and a second vertical height; a plurality of coupling pads between the HBM controller die and the plurality of DRAM dies; chip coupling insulating layers, each of the chip coupling insulating layers surrounding the plurality of coupling pads and provided between the HBM controller die and the plurality of DRAM dies; a support dummy substrate on the plurality of DRAM dies, the support dummy substrate having a third horizontal width that is equal to the second horizontal width of at least one DRAM die of the plurality of DRAM dies and a third vertical height that is greater than the first vertical height of the HBM controller die and the second vertical height of the at least one DRAM die of the plurality of DRAM dies; a support coupling insulating layer on an inactive surface of an uppermost DRAM die among the plurality of DRAM dies; a plurality of chip pads on a surface of the support coupling insulating layer that faces the support dummy substrate; and a molding layer provided on the HBM controller die, the molding layer covering an upper surface of the HBM controller die, side surfaces and an upper surface of the plurality of DRAM dies, and side surfaces and a lower surface of the support dummy substrate, wherein the molding layer exposes an upper surface of the support dummy substrate without covering the upper surface of the support dummy substrate, wherein the support dummy substrate includes a plurality of solder balls on the lower surface of the support dummy substrate that faces the upper surface of the support coupling insulating layer, and the plurality of solder balls are bonded to the plurality of chip pads.

### BRIEF DESCRIPTION OF THE DRAWINGS

The above and/or other aspects will be more clearly understood from the following detailed description of embodiments taken in conjunction with the accompanying drawings, in which:

FIG. 1 is a cross-sectional view showing a semiconductor package according to an embodiment;

FIG. 2 is an enlarged view of region P1 of FIG. 1;

FIG. 3 is a cross-sectional view showing a semiconductor package according to another embodiment;

FIG. 4 is an enlarged view of region P2 of FIG. 3;

FIGS. 5, 6, 7, 8, and 9 are cross-sectional views showing semiconductor packages according to some embodiments; and

FIGS. 10 to 17 are cross-sectional views sequentially showing a process of manufacturing a semiconductor package, according to an embodiment.

### DETAILED DESCRIPTION

Hereinafter, embodiments are described in detail with reference to the accompanying drawings. The embodiments of the disclosure may, however, be embodied in different forms and should not be construed as limited to the embodiments set forth herein. The following embodiments are provided to sufficiently convey the scope of the disclosure to those skilled in the art rather than to make the present disclosure thorough and complete.

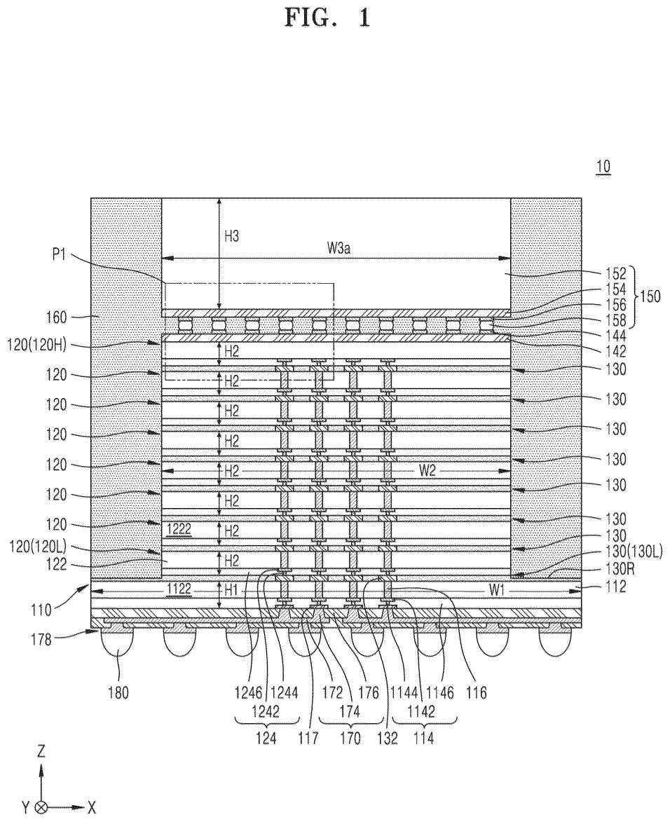

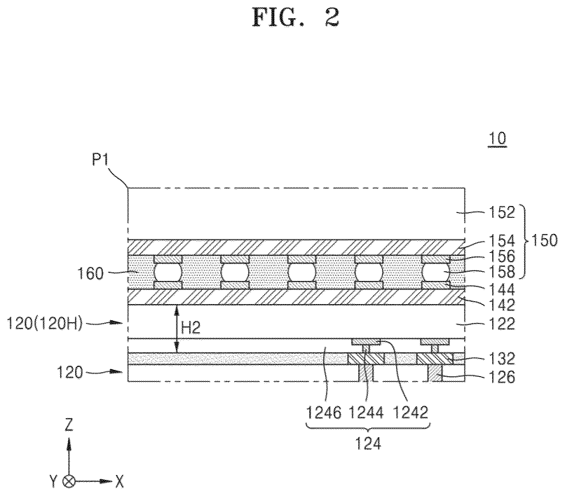

FIG. 1 is a cross-sectional view showing a semiconductor package 10 according to an embodiment and FIG. 2 is an enlarged view of region P1 of FIG. 1.

Referring to FIG. 1, the semiconductor package 10 includes a first semiconductor chip 110 and a plurality of second semiconductor chips 120 stacked in a vertical direction (Z direction). Although the semiconductor package 10 shown in FIG. 1 includes eight second semiconductor chips 120, embodiments of the disclosure are not limited thereto. For example, the semiconductor package 10 may include two or more second semiconductor chips 120. In some embodiments, the number of second semiconductor chips 120 included in the semiconductor package 10 may be a multiple of 4. The plurality of second semiconductor chips 120 may be sequentially stacked on the first semiconductor chip 110. For convenience of description, a second semiconductor chip 120L that is lowermost among the plurality of second semiconductor chips 120 may be referred to as a lowermost second semiconductor chip 120L and a second semiconductor chip 120H that is uppermost among the plurality of second semiconductor chips 120 may be referred to as an uppermost second semiconductor chip 120H. In this specification, a direction, which is perpendicular to the upper surface of the first semiconductor chip 110, may be defined as a vertical direction (Z direction) and a direction, which is parallel to the upper surface of the first semiconductor chip 110 and in which a plurality of first electrodes 116 are sequentially arranged, may be defined as a first horizontal direction (X direction). Also, a direction, which is perpendicular to the first horizontal direction (X direction), may be defined as a second horizontal direction (Y direction).

The first semiconductor chip 110 and the plurality of second semiconductor chips 120 in the semiconductor package 10 may be electrically connected to each other through a plurality of coupling pads 132 to exchange signals and provide power and ground. For example, the plurality of coupling pads 132 may be arranged between the first semiconductor chip 110 and the lowermost second semiconductor chip 120L and between two neighboring second semiconductor chips 120.

For example, the plurality of coupling pads 132 may include a material containing Cu. A coupling pad 132, located between the first semiconductor chip 110 and the lowermost second semiconductor chip 120L, among the plurality of coupling pads 132 may be referred to as a first coupling pad and a coupling pad 132, located between two neighboring second semiconductor chips 120, among the plurality of coupling pads 132 may be referred to as a second coupling pad.

The first semiconductor chip 110 may include a first semiconductor substrate 112 having an active surface and an inactive surfaces opposite to each other, a first semiconductor element 1122 formed on the active surface of the first semiconductor substrate 112, a first wiring structure 114 formed on the active surface of the first semiconductor substrate 112, and a plurality of first electrodes 116 connected to the first wiring structure 114 and passing or penetrating through at least a portion of the first semiconductor chip 110. The first semiconductor chip 110 may further include a plurality of lower chip pads 117 which are arranged on the lower surface of the first semiconductor chip 110 and electrically connected to a first wiring pattern 1142 and/or a first wiring via 1144. The plurality of lower chip pads 117 may be electrically connected to the first semiconductor element 1122 or the first wiring structure 114 through the first wiring pattern 1142 and/or the first wiring via 1144.

In the semiconductor package 10, the first semiconductor chip 110 may be arranged such that the active surface of the first semiconductor substrate 112 faces down and the inactive surface of the first semiconductor substrate 112 faces up. Therefore, in the semiconductor package 10, unless otherwise stated herein, the upper surface of the first semiconductor chip 110 refers to the side toward which the inactive surface of the first semiconductor substrate 112 is directed and the lower surface of the first semiconductor chip 110 refers to the side toward which the active surface of the first semiconductor substrate 112 is directed. However, when describing the above surfaces on the basis of the first semiconductor chip 110, the lower surface of the first semiconductor chip 110 toward which the active surface of the first semiconductor substrate 112 is directed may be referred to as a front surface of the first semiconductor chip 110 and the upper surface of the first semiconductor chip 110 toward which the inactive surface of the first semiconductor substrate 112 is directed may be referred to as a back surface of the first semiconductor chip 110.

Each of the second semiconductor chips 120 may include a second semiconductor substrate 122 having an active surface and an inactive surfaces opposite to each other, a second semiconductor element 1222 formed on the active surface of the second semiconductor substrate 122, and a second wiring structure 124 formed on the active surface of the second semiconductor substrate 122.

Each of the plurality of second semiconductor chips 120 may include a plurality of second electrodes 126, which are connected to the second wiring structure 124 and pass or penetrate through at least a portion of the second semiconductor chip 120. The uppermost second semiconductor chip 120H, which is the second semiconductor chip 120 located farthest from the first semiconductor chip 110 and located uppermost in the semiconductor package 10, among the plurality of second semiconductor chips 120 may not include the plurality of second electrodes 126.

In some embodiments, the vertical height, that is, the thickness, of the uppermost second semiconductor chip 120H among the plurality of second semiconductor chips 120 may be substantially the same as the vertical height, that is, the thickness, of the other second semiconductor chips 120 among the plurality of second semiconductor chips 120.

In the semiconductor package 10, the plurality of second semiconductor chips 120 may be sequentially stacked on the first semiconductor chip 110 in the vertical direction with each of the active surfaces of the second semiconductor chips 120 directed downward, that is, toward the first semiconductor chip 110. Therefore, in the semiconductor package 10, unless otherwise stated herein, the upper surface of the second semiconductor chip 120 refers to the side toward which the inactive surface of the second semiconductor substrate 122 is directed and the lower surface of the second semiconductor chip 120 refers to the side toward which the active surface of the second semiconductor substrate 122 is directed. However, when describing the above surfaces on the basis of the second semiconductor chip 120, the lower surface of the second semiconductor chip 120 toward which the active surface of the second semiconductor substrate 122 is directed may be referred to as a front surface of the second semiconductor chip 120 and the upper surface of the second semiconductor chip 120 toward which the inactive surface of the second semiconductor substrate 122 is directed may be referred to as a back surface of the second semiconductor chip 120.

The first semiconductor substrate 112 and the second semiconductor substrate 122 may include, for example, a semiconductor material, such as silicon (Si). Also, the first semiconductor substrate 112 and the second semiconductor substrate 122 may include a semiconductor material, such as germanium (Ge). Each of the first semiconductor substrate 112 and the second semiconductor substrate 122 may have an active surface and an inactive surface opposite to the active surface. The first semiconductor substrate 112 and the second semiconductor substrate 122 may include a conductive region, for example, a well doped with impurities. The first semiconductor substrate 112 and the second semiconductor substrate 122 may have various device isolation structures, such as a shallow trench isolation (STI) structure.

Each of the first semiconductor element 1122 and the second semiconductor element 1222 may include a plurality of various types of individual devices. The plurality of individual devices may include various microelectronic devices, for example, metal-oxide-semiconductor field effect transistors (MOSFET), such as complementary metal-oxide-semiconductor (CMOS) transistors, system large scale integration (LSI), image sensors, such as CMOS imaging sensors (CIS), micro-electro-mechanical systems (MEMS), active elements, passive elements, etc. The plurality of individual devices may be electrically connected to the conductive region of the first semiconductor substrate 112 or the second semiconductor substrate 122. Each of the first semiconductor element 1122 and the second semiconductor element 1222 may further include a conductive wire or a conductive plug that electrically connects at least two of the plurality of individual devices or electrically connects the plurality of individual devices to the conductive region of each of the first semiconductor substrate 112 and the second semiconductor substrate 122. Also, the plurality of individual devices may be electrically separated from other neighboring individual devices by an insulating film.

At least one of the first semiconductor chip 110 and the second semiconductor chip 120 may include a memory semiconductor chip. In some embodiments, the first semiconductor chip 110 may be provided with a serial-parallel conversion circuit and include a buffer chip for controlling the plurality of second semiconductor chips 120. The plurality of second semiconductor chips 120 may include memory chips including memory cells. For example, the semiconductor package 10 including the first semiconductor chip 110 and the plurality of second semiconductor chips 120 may include high bandwidth memory (HBM). The first semiconductor chip 110 may be referred to as an HBM controller die and each of the plurality of second semiconductor chips 120 may be referred to as a dynamic random access memory (DRAM) die.

The first wiring structure 114 may include a plurality of first wiring patterns 1142, a plurality of first wiring vias 1144 connected to the plurality of first wiring patterns 1142, and a first inter-wiring insulating layer 1146 surrounding the plurality of first wiring patterns 1142 and the plurality of first wiring vias 1144. In some embodiments, each of the plurality of first wiring patterns 1142 may have a thickness of about 0.5 micrometer or less. In some embodiments, the first wiring structure 114 may have a multi-layer wiring structure including the first wiring patterns 1142 and the first wiring vias 1144 that are at different vertical levels.

The second wiring structure 124 may include a plurality of second wiring patterns 1242, a plurality of second wiring vias 1244 connected to the plurality of second wiring patterns 1242, and a second inter-wiring insulating layer 1246 surrounding the plurality of second wiring patterns 1242 and the plurality of second wiring vias 1244. In some embodiments, each of the plurality of second wiring patterns 1242 may have a thickness of about 0.5 micrometer or less. In some embodiments, the second wiring structure 124 may have a multi-layer wiring structure including the second wiring patterns 1242 and the second wiring vias 1244 that are at different vertical levels.

The plurality of first wiring patterns 1142, the plurality of first wiring vias 1144, the plurality of second wiring patterns 1242, and the plurality of second wiring vias 1244 may include, for example, metal materials, such as aluminum, copper, and tungsten. In some embodiments, the plurality of first wiring patterns 1142, the plurality of first wiring vias 1144, the plurality of second wiring patterns 1242, and the plurality of second wiring vias 1244 include a wiring barrier film and a wiring metal layer. The wiring barrier film may include metal, metal nitride, or alloy. The wiring metal layer may include one metal selected from among W, Al, Ti, Ta, Ru, Mn, and Cu.

When the first wiring structure 114 and the second wiring structure 124 have a multi-layer wiring structure, the first inter-wiring insulating layer 1146 and the second inter-wiring insulating layer 1246 may have a multi-layer structure in which a plurality of insulating layers are stacked, corresponding to the multi-layer wiring structure of the first wiring structure 114 and the second wiring structure 124. For example, the first inter-wiring insulating layer 1146 and the second inter-wiring insulating layer 1246 may include silicon oxide, silicon nitride, silicon oxynitride, an insulating material with lower permittivity than the silicon oxide, or a combination thereof. In some embodiments, the first inter-wiring insulating layer 1146 and the second inter-wiring insulating layer 1246 may include a tetraethyl orthosilicate (TEOS) film or an ultralow K (ULK) film having an ultralow dielectric constant K of about 2.2 to about 2.4. The ULK film may include an SiOC film or an SiCOH film.

Each of the first electrodes 116 and the second electrodes 126 may be provided in the form of a through silicon via (TSV). The first electrodes 116 and the second electrodes 126 may include conductive plugs respectively passing or penetrating through the first semiconductor substrate 112 and the second semiconductor substrate 122 and conductive barrier films surrounding the conductive plugs. Each of the conductive plugs may have a cylindrical shape and each of the conductive barrier films may have a cylinder shape surrounding a sidewall of the conductive plug. A via insulating film may be located between the first electrode 116 and the first semiconductor substrate 112 and between the second electrode 126 and the second semiconductor substrate 122 and may surround sidewalls of the first electrode 116 and the second electrode 126. The first electrode 116 and the second electrode 126 may have any one of a via-first structure, a via-middle structure, and a via-last structure.

The first semiconductor chip 110 may have a first horizontal width W1 and a first vertical height H1 and each of the plurality of second semiconductor chips 120 may have a second horizontal width W2 and a second vertical height H2. In some embodiments, the first horizontal width W1 may be greater than the second horizontal width W2. In some embodiments, the first vertical height H1 may be substantially equal to the second vertical height H2. For example, the first vertical height H1 and the second vertical height H2 may be about 50 micrometers to about 70 micrometers.

The plurality of coupling pads 132 may electrically connect the second wiring patterns 1242 and/or the second wiring vias 1244 of the second wiring structure 124 to the plurality of first electrodes 116 or the plurality of second electrodes 126, which are located below the second wiring structure 124.

For example, the second wiring patterns 1242 and/or the second wiring vias 1244 of the second wiring structure 124 of the lowermost second semiconductor chip 120L may be electrically connected to the plurality of first electrodes 116 of the first semiconductor chip 110 located below the lowermost second semiconductor chip 120L, through the plurality of coupling pads 132, that is, a plurality of first coupling pads. Also, the second wiring patterns 1242 and/or the second wiring vias 1244 of the second wiring structure 124 of another second semiconductor chip 120 other than the lowermost second semiconductor chip 120L may be electrically connected to the plurality of second electrodes 126 of the second semiconductor chip 120 located below another second semiconductor chip 120 stated above, through the plurality of coupling pads 132, that is, a plurality of second coupling pads.

The plurality of coupling pads 132 may be surrounded by a chip coupling insulating layer 130 between the first semiconductor chip 110 and the plurality of second semiconductor chips 120, that is, between the first semiconductor chip 110 and the lowermost second semiconductor chip 120L and between the plurality of second semiconductor chips 120 adjacent to each other. The plurality of coupling pads 132 may pass or penetrate through the chip coupling insulating layer 130. A plurality of chip coupling insulating layers 130 may be respectively provided in spaces or areas between the first semiconductor chip 110 and the plurality of second semiconductor chips 120.

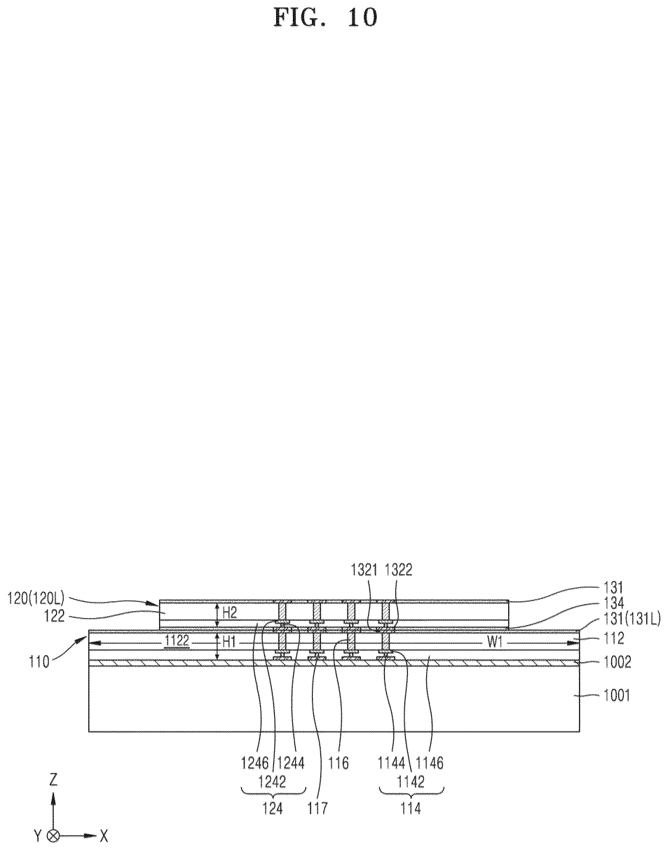

Each of the plurality of coupling pads 132 may be formed by diffusion bonding of: respectively forming conductive material layers, for example, a plurality of upper chip connection pads 1321 and a plurality of lower chip connection pads 1322 shown in FIG. 10, on facing surfaces of two adjacent chips among the first semiconductor chip 110 and the plurality of second semiconductor chips 120; expanding the facing conductive material layers using heat to bring the conductive material layers into contact with each other; and diffusing metal atoms contained in the conductive material layers so that the conductive material layers are integrated with each other.

The chip coupling insulating layer 130 may be formed, during the formation of the plurality of coupling pads 132, by diffusion bonding of: respectively forming insulating material layers, for example, an upper chip coupling insulating material layer 131 and a lower chip coupling insulating material layer 134 shown in FIG. 10, on facing surfaces of two adjacent chips among the first semiconductor chip 110 and the plurality of second semiconductor chips 120; expanding the facing insulating material layers using heat to bring the insulating material layers into contact with each other; and diffusing atoms contained in the insulating material layers so that the insulating material layers are integrated with each other.

A lowermost chip coupling insulating layer 130L, located between the first semiconductor chip 110 and the lowermost second semiconductor chip 120L, among the plurality of chip coupling insulating layers 130 may be formed by performing the diffusion bonding on an insulating material layer covering the upper surface of the first semiconductor chip 110 and an insulating material layer covering the lower surface of the lowermost second semiconductor chip 120L, for example, by performing the diffusion bonding on a lowermost upper chip coupling insulating material layer 131 and a lowermost lower chip coupling insulating material layer 134 which are shown in FIG. 10.

The lowermost chip coupling insulating layer 130L may have a recess 130R formed in an upper portion thereof so that the thickness of a portion of the lowermost chip coupling insulating layer 130L, overlapping the lowermost second semiconductor chip 120L in the vertical direction, is greater than the thickness of a portion of the lowermost chip coupling insulating layer 130L, not overlapping the lowermost second semiconductor chip 120L in the vertical direction. The recess 130R may be located in a portion of the lowermost chip coupling insulating layer 130L that does not overlap the lowermost second semiconductor chip 120L in the vertical direction. The lowermost chip coupling insulating layer 130L may have a flat lower surface. Also, a middle portion of the lowermost chip coupling insulating layer 130L, that is, the portion overlapping the lowermost second semiconductor chip 120L in the vertical direction, may protrude upward from an edge portion of the lowermost chip coupling insulating layer 130L, that is, the portion not overlapping the lowermost second semiconductor chip 120L in the vertical direction.

The lowermost chip coupling insulating layer 130L may entirely cover the upper surface of the first semiconductor chip 110 that does not overlap the lowermost second semiconductor chip 120L in the vertical direction. A portion of the upper surface of the first semiconductor chip 110 that overlaps the lowermost second semiconductor chip 120L in the vertical direction and a portion of the lower surface of the lowermost second semiconductor chip 120L may be covered by the plurality of coupling pads 132. The other portions may be covered by the lowermost chip coupling insulating layer 130L.

Each of the chip coupling insulating layers 130 other than the lowermost chip coupling insulating layer 130L may cover, together with the plurality of coupling pads 132, both the upper and lower surfaces of the facing second semiconductor chips 120. The chip coupling insulating layers 130 other than the lowermost chip coupling insulating layer 130L may have flat upper and lower surfaces and substantially the same thickness.

The lowermost chip coupling insulating layer 130L may have the first horizontal width W1 and each of the chip coupling insulating layers 130 other than the lowermost chip coupling insulating layer 130L may have the second horizontal width W2. The chip coupling insulating layers 130 other than the lowermost chip coupling insulating layer 130L may overlap the plurality of second semiconductor chips 120 in the vertical direction. The side surfaces of the chip coupling insulating layers 130 other than the lowermost chip coupling insulating layer 130L and the side surfaces of the second semiconductor chips 120 may be aligned with each other to form a coplanar plane.

The chip coupling insulating layer 130 may include any one of SiO, SiN, SiCN, SiCO, and a polymer material. The polymer material may include benzocyclobutene (BCB), polyimide (PI), polybenzoxazole (PBO), silicone, acrylate, or epoxy. For example, the chip coupling insulating layer 130 may include silicon oxide. The chip coupling insulating layer 130 may have a thickness of, for example, about 100 nanometers to about 1 micrometer.

According to an embodiment, the semiconductor package 10 may further include a first support insulating layer 142 disposed on the inactive surface of the uppermost second semiconductor chip 120H. The first support insulating layer 142 may have a constant thickness and cover the inactive surface of the uppermost second semiconductor chip 120H. The shape of the upper surface of the first support insulating layer 142 may match the shape of the inactive surface of the uppermost second semiconductor chip 120H, and the first support insulating layer 142 may completely overlap the inactive surface of the uppermost second semiconductor chip 120H. That is, the side surfaces of the first support insulating layer 142 and the uppermost second semiconductor chip 120H may be aligned with each other in the vertical direction (Z direction) to form a coplanar plane. The thickness of the first support insulating layer 142 may be less than the thickness of the second semiconductor substrate 122 of the second semiconductor chip 120. The upper surface of the first support insulating layer 142 may have the same area as the upper surface of the uppermost second semiconductor chip 120H. That is, the first support insulating layer 142 may have the second horizontal width W2. According to an embodiment, the first support insulating layer 142 may include silicon nitride.

According to an embodiment, the semiconductor package 10 may further include a plurality of chip pads 144, which are disposed on the upper surface of the first support insulating layer 142 facing a support dummy substrate 150. The plurality of chip pads 144 may be arranged in a direction parallel to the upper surface of the first support insulating layer 142. As shown in detail in FIG. 2, the plurality of chip pads 144 are formed on the upper surface of the first support insulating layer 142 and are not buried inside the first support insulating layer 142. The plurality of chip pads 144 are not electrically connected to the second semiconductor element 1222 that is located inside the second semiconductor substrate 122 of the uppermost second semiconductor chip 120H. Therefore, even if the plurality of chip pads 144 are exposed to the outside, there is little risk of an electrical short circuit occurring in the relationship with the second semiconductor element 1222 located inside the second semiconductor chip 120. The plurality of chip pads 144 may include a conductive material, for example, nickel (Ni), gold (Au), copper (Cu), or a combination thereof.

The support dummy substrate 150 may be stacked above or on the uppermost second semiconductor chip 120H. The support dummy substrate 150 may include a body 152, a second support insulating layer 154, a connection pad 156, and a solder ball 158. The body 152 of the support dummy substrate 150 may include, for example, a semiconductor material, such as silicon (Si). In some embodiments, the body 152 may include only the semiconductor material. For example, the body 152 may include a portion of a bare wafer.

The body 152 of the support dummy substrate 150 may have a third horizontal width W3a and a third vertical height H3. In some embodiments, the third horizontal width W3a may be less than the first horizontal width W1 and the second horizontal width W2. In some embodiments, the third vertical height H3 may be greater than the first vertical height H1 and the second vertical height H2. For example, the third vertical height H3 may be about 100 micrometers to about 500 micrometers. Strictly speaking, the third vertical height H3 refers to the vertical height of the body 152 of the support dummy substrate 150. However, since the vertical height of the second support insulating layer 154 is very small compared to the vertical height of the body 152, the third vertical height H3 is substantially equal to the vertical height of the support dummy substrate 150. The side surfaces of the support dummy substrate 150 and the side surfaces of the second semiconductor chips 120 may be aligned with each other in the vertical direction (Z direction) to form a coplanar plane.

The second support insulating layer 154 of the support dummy substrate 150 may have a constant thickness and cover the lower surface of the body 152 facing the second semiconductor chips 120. The shape of the lower surface of the second support insulating layer 154 may match the shape of the lower surface of the body 152, and the second support insulating layer 154 may completely overlap the lower surface of the body 152. That is, the side surfaces of the second support insulating layer 154 and the side surfaces of the body 152 may be aligned with each other in the vertical direction (Z direction) to form a coplanar plane. According to an embodiment, the second support insulating layer 154 may include silicon nitride.

According to an embodiment, connection pads 156 may be disposed on the lower surface of the second support insulating layer 154 facing the second semiconductor chip 120. The plurality of connection pads 156 may be arranged in a direction parallel to the lower surface of the second support insulating layer 154. As shown in detail in FIG. 2, the plurality of connection pads 156 are formed on the lower surface of the second support insulating layer 154 and are not buried inside the second support insulating layer 154. The support dummy substrate 150 does not include semiconductor devices. Accordingly, even if the connection pads 156 are exposed to the outside of the body 152, there may be less factors that deteriorate the reliability of the semiconductor package 10 due to an electrical short circuit. The plurality of connection pads 156 may include a conductive material, for example, nickel (Ni), gold (Au), copper (Cu), or a combination thereof.

According to an embodiment, a plurality of solder balls 158 may be respectively attached to the plurality of connection pads 156. The solder ball 158 may include metal, such as a solder material. For example, the solder material may include tin (Sn), silver (Ag), zinc (Zn), and/or an alloy thereof. The solder balls 158 may be arranged between the body 152 of the support dummy substrate 150 and the uppermost second semiconductor chip 120H and electrically connect the connection pads 156 and the chip pads 144 to each other. However, since no semiconductor device is provided inside the support dummy substrate 150, the uppermost second semiconductor chip 120H and the body 152 of the support dummy substrate 150 may not be electrically connected to each other. According to an embodiment, the solder balls 158 may be entirely surrounded inside edges of the lower surface of the first support dummy substrate 150 in a plan view.

The uppermost second semiconductor chip 120H and the support dummy substrate 150 may be spaced apart in the vertical direction (Z direction) by a certain distance. Strictly speaking, the upper surface of the first support insulating layer 142 and the lower surface of the second support insulating layer 154 of the support dummy substrate 150 may be spaced apart from each other by a certain distance. The first semiconductor chip 110 and the plurality of second semiconductor chips 120 have a relatively small thickness in the vertical direction (Z direction) compared to the widths thereof in the horizontal direction, and thus, the upper surfaces of the first semiconductor chip 110 and the plurality of second semiconductor chips 120 may have a sinuous wave shape. Here, when the first semiconductor chip 110 and the plurality of second semiconductor chips 120 are stacked by hybrid bonding, wave shapes of the upper surfaces of the first semiconductor chip 110 and the plurality of second semiconductor chips 120 are accumulated, and thus, the upper surface of the uppermost second semiconductor chip 120H may have a large curve. The uppermost second semiconductor chip 120H and the support dummy substrate 150 are bonded using the solder balls 158 with a distance rather than hybrid bonding, and thus, it is possible to avoid the occurrence of voids due to surface-to-face adhesion. As described in detail below, a molding layer 160 may be buried between the uppermost second semiconductor chip 120H and the support dummy substrate 150 to fill an empty space (an empty area).

The semiconductor package 10 may further include the molding layer 160, which is provided on the first semiconductor chip 110, covers the upper surface of the first semiconductor chip 110, and surrounds the side surfaces of the plurality of second semiconductor chips 120 and the support dummy substrate 150. The molding layer 160 may be buried in the space (the area) between the uppermost second semiconductor chip 120H and the support dummy substrate 150. Strictly speaking, the molding layer 160 may be buried in the space (the area) between the upper surface of the first support insulating layer 142 and the lower surface of the second support insulating layer 154 in the support dummy substrate 150. The molding layer 160 may be buried between the uppermost second semiconductor chip 120H and the support dummy substrate 150 and surround the plurality of solder balls 158. That is, the molding layer 160 may fill the space (the area) between the support dummy substrate 150 and the uppermost second semiconductor chip 120H and surround the solder balls 158. Even if the plurality of second semiconductor chips 120 are stacked by hybrid bonding and the upper surface of the uppermost second semiconductor chip 120H or the upper surface of the first support insulating layer 142 is curved, the molding layer 160 may fill the space (the area) between curves and prevent voids from occurring.

The molding layer 160 may include, for example, an epoxy molding compound (EMC). In some embodiments, the molding layer 160 may cover the upper surface of the support dummy substrate 150. In some other embodiments, the molding layer 160 may not cover the upper surface of the support dummy substrate 150. For example, a heat dissipation member may be attached to the support dummy substrate 150 with a thermal interface material (TIM) layer therebetween.

In some embodiments, the semiconductor package 10 may further include a base redistribution layer 170 disposed on the lower surface of the first semiconductor chip 110. The base redistribution layer 170 may include a plurality of package redistribution line patterns 172, a plurality of package redistribution vias 174, and a package redistribution insulating layer 176. In some embodiments, a plurality of package redistribution insulating layers 176 may be stacked. The package redistribution insulating layer 176 may be formed from, for example, photo imageable dielectric (PID) or photosensitive polyimide (PSPI). Each of the package redistribution line patterns 172 and the package redistribution vias 174 may include, for example, metals, such as copper (Cu), aluminum (Al), tungsten (W), titanium (Ti), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof. However, embodiments of the disclosure are not limited thereto. In some embodiments, the package redistribution line pattern 172 and the package redistribution via 174 may be formed by stacking a metal or a metal alloy on a seed layer including titanium, titanium nitride, or titanium tungsten.

The plurality of package redistribution line patterns 172 may be disposed on at least one of the upper surface and the lower surface of the package redistribution insulating layer 176. The plurality of package redistribution vias 174 may pass or penetrate through the package redistribution insulating layer 176 and be brought into contact with and connected to some of the plurality of package redistribution line patterns 172. In some embodiments, at least some of the plurality of package redistribution line patterns 172 may be formed together with some of the plurality of package redistribution vias 174 to form an integrated body. For example, the package redistribution line pattern 172 and the package redistribution via 174 in contact with the upper surface of the package redistribution line pattern 172 may be integrated with each other. The package redistribution insulating layer 176 may surround the plurality of package redistribution line patterns 172 and the plurality of package redistribution vias 174.

The plurality of package redistribution line patterns 172 and the plurality of package redistribution vias 174 may be electrically connected to the plurality of lower chip pads 117. In some embodiments, at least some of the plurality of package redistribution vias 174 may be in contact with the plurality of lower chip pads 117. For example, when the semiconductor package 10 includes a plurality of package redistribution insulating layers 176 in which the package redistribution line patterns 172 and the package redistribution vias 174 are stacked, the package redistribution vias 174 passing or penetrating through an uppermost package redistribution insulating layer 176 may be in contact with and electrically connected to the lower chip pads 117.

In some embodiments, the plurality of package redistribution vias 174 may each have a tapered shape extending from the bottom to the top with a decreasing horizontal width. That is, the horizontal width of each of the plurality of package redistribution vias 174 may increase in a direction away from the first semiconductor chip 110.

A package redistribution line pattern 172, which is disposed on the lower surface of the base redistribution layer 170, among the plurality of package redistribution line patterns 172 may be referred to as a package pad 178. A plurality of package connection terminals 180 may be respectively attached to a plurality of package pads 178. For example, each of the package connection terminals 180 may include a solder ball or a bump.

In embodiments, the semiconductor package 10 may not include the base redistribution layer 170. For example, the plurality of package connection terminals 180 may be attached to the plurality of lower chip pads 117.

The horizontal width and horizontal area of the base redistribution layer 170 may be same as the horizontal width and horizontal area of the first semiconductor chip 110. The base redistribution layer 170 and the first semiconductor chip 110 may overlap each other in the vertical direction (Z direction).

For example, the horizontal widths and horizontal areas of the base redistribution layer 170, the first semiconductor chip 110, and the molding layer 160 may be substantially the same. The side surfaces of the base redistribution layer 170, the first semiconductor chip 110, and the molding layer 160 may be aligned with each other in the vertical direction (Z direction) to form a coplanar plane.

The semiconductor package 10 according to the disclosure may be formed by stacking the first semiconductor chip 110 and the plurality of second semiconductor chips 120, through the hybrid bonding that forms the plurality of coupling pads 132 and the chip coupling insulating layer 130 by diffusion bonding.

Since the semiconductor package 10 according to the disclosure has a support dummy substrate 150 having a relatively large thickness (vertical height), the structural reliability of the semiconductor package 10 may be improved, and heat may be smoothly discharged to the outside of the semiconductor package 10 through the support dummy substrate 150. The support dummy substrate 150 and the uppermost second semiconductor chip 120H are bonded to each other by the solder balls 158.

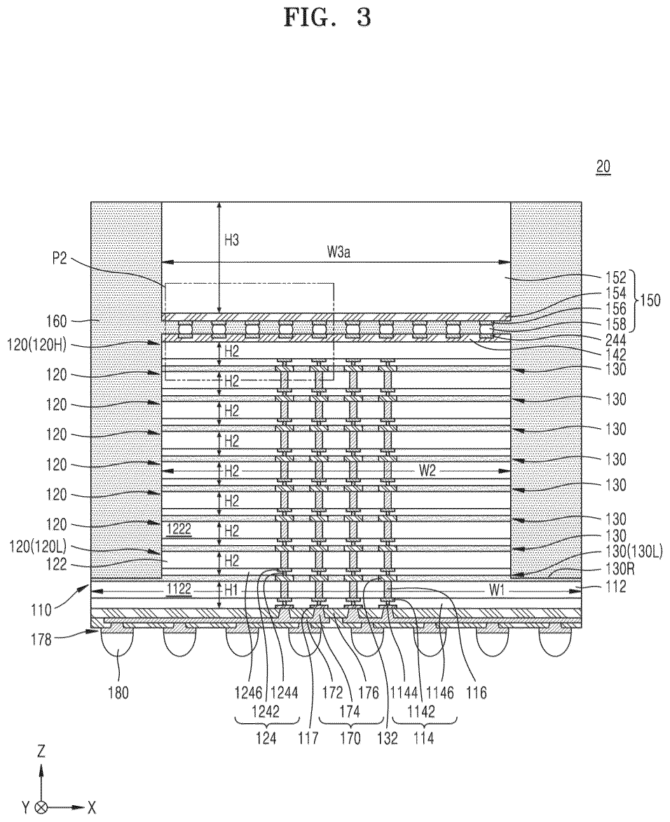

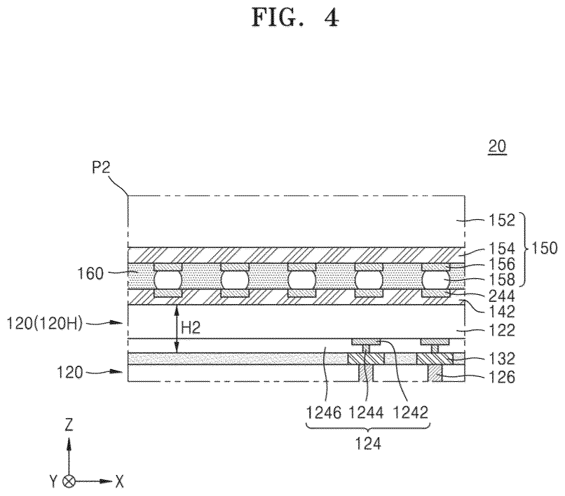

FIG. 3 is a cross-sectional view showing a semiconductor package 20 according to another embodiment and FIG. 4 is an enlarged view of region P2 of FIG. 3. The semiconductor package 20 shown in FIGS. 3 and 4 is substantially the same as or similar to the semiconductor package 10 shown in FIGS. 1 and 2, except that the locations of chip pads 244 shown in FIGS. 3 and 4 are different from locations of the chip pads 144 shown in FIGS. 1 and 2. Therefore, descriptions of the components already given above with reference to FIGS. 1 and 2 are omitted or briefly given.

Referring to FIGS. 3 and 4, the plurality of chip pads 244 may be disposed on the upper surface of a first support insulating layer 142 facing a support dummy substrate 150. The plurality of chip pads 244 may be arranged in a direction parallel to the upper surface of the first support insulating layer 142. As shown in detail in FIG. 4, the plurality of chip pads 244 may be buried inside the first support insulating layer 142. That is, the upper surfaces of the plurality of chip pads 244 may be coplanar with the upper surface of the first support insulating layer 142. The plurality of chip pads 244 are respectively bonded to the solder balls 158, and thus, the plurality of chip pads 244 may not be exposed to the outside, unlike the plurality of chip pads 144 shown in FIGS. 1 and 2. Since the plurality of chip pads 244 including a conductive material are buried inside the first support insulating layer 142 including an insulating material, the probability of an electrical short circuit occurring between the plurality of chip pads 244 may be reduced.

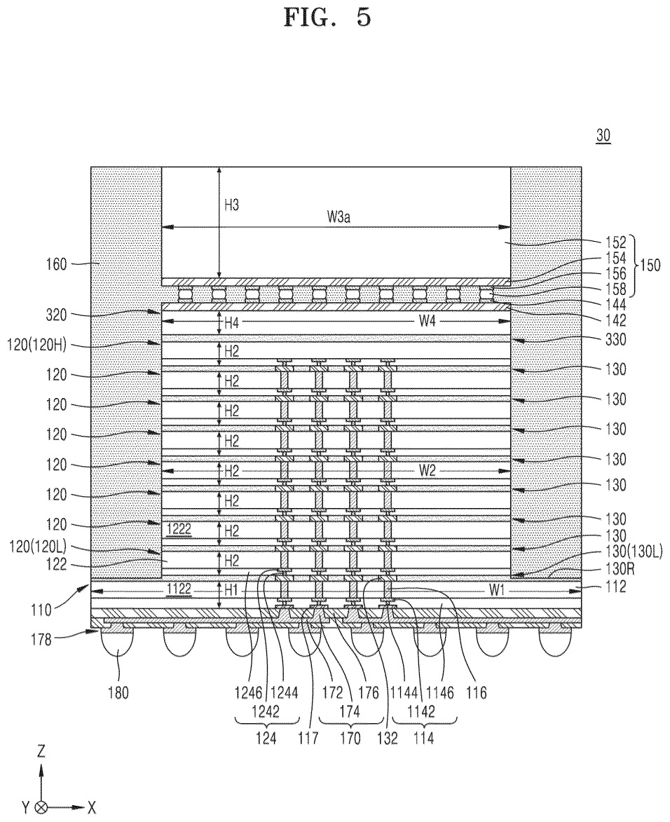

FIGS. 5, 6, 7, 8, and 9 are cross-sectional views showing semiconductor packages 30, 40, 50, 60, and 70 according to some embodiments.

The semiconductor package 30 illustrated in FIG. 5 may be substantially the same as or similar to the semiconductor package 10 illustrated in FIGS. 1 and 2, except that the semiconductor package 30 further includes a second support dummy substrate 320. Therefore, descriptions of the components already given above with reference to FIGS. 1 and 2 are omitted or briefly given.

Referring to FIG. 5, the semiconductor package 30 may include a first support dummy substrate 150 stacked above or on an uppermost second semiconductor chip 120H and the second support dummy substrate 320 disposed between the first support dummy substrate 150 and the uppermost second semiconductor chip 120H. The first support dummy substrate 150 may be substantially the same as the support dummy substrate 150 shown in FIGS. 1 and 2.

According to an embodiment, a substrate coupling insulating layer 330 may be disposed on the upper surface of the uppermost second semiconductor chip 120H. A coupling pad 132 is not buried in the substrate coupling insulating layer 330, unlike in a plurality of chip coupling insulating layers 130. The substrate coupling insulating layer 330 may have a constant thickness and cover the inactive surface of the uppermost second semiconductor chip 120H. The shape of the upper surface of the substrate coupling insulating layer 330 may match the shape of the inactive surface of the uppermost second semiconductor chip 120H, and the substrate coupling insulating layer 330 may completely overlap the inactive surface of the uppermost second semiconductor chip 120H. That is, the side surfaces of the substrate coupling insulating layer 330 and the uppermost second semiconductor chip 120H may be aligned with each other in the vertical direction (Z direction) to form a coplanar plane. The substrate coupling insulating layer 330 may have substantially the same configuration as the chip coupling insulating layer 130. That is, the substrate coupling insulating layer 330 may be formed by diffusion bonding of: expanding facing insulating material layers using heat to bring the insulating material layers into contact with each other; and diffusing atoms contained in the insulating material layers so that the insulating material layers are integrated with each other.

According to an embodiment, the second support dummy substrate 320 may be disposed on the substrate coupling insulating layer 330. The second support dummy substrate 320 may have a fourth horizontal width W4 and a fourth vertical height H4. Here, the fourth horizontal width W4 may be substantially equal to a second horizontal width W2 of a second semiconductor chip 120 and the fourth vertical height H4 may be substantially equal to a second vertical height H2 of the second semiconductor chip 120. The second support dummy substrate 320 may include, for example, a semiconductor material, such as silicon. In some embodiments, the second support dummy substrate 320 may include only the semiconductor material. For example, the second support dummy substrate 320 may include a portion of a bare wafer. Unlike a plurality of second semiconductor chips 120, the second support dummy substrate 320 may not include a semiconductor device therein. A first support insulating layer 142 may be disposed on the second support dummy substrate 320, and a plurality of chip pads 144 may be arranged on the upper surface of the first support insulating layer 142 in the first horizontal direction (X direction) or the second horizontal direction (Y direction). In the semiconductor package 10 shown in FIGS. 1 and 2, the second semiconductor chips 120 including the second semiconductor elements 1222 are sequentially stacked, and then the first support insulating layer 142 and the plurality of chip pads 144 are formed on the uppermost second semiconductor chip 120H. On the other hand, the semiconductor package 30 shown in FIG. 5 may be formed by stacking, on the uppermost second semiconductor chip 120H, the second support dummy substrate 320 on which the first support insulating layer 142 and the plurality of chip pads 144 have been formed. Accordingly, the semiconductor package 30 may be manufactured through a more efficient process.

The semiconductor package 30 may further include a molding layer 160, which is provided on a first semiconductor chip 110, covers the upper surface of the first semiconductor chip 110, and surrounds the side surfaces of the plurality of second semiconductor chips 120, the side surfaces of the second support dummy substrate 320, and the side surfaces of the first support dummy substrate 150. In addition, the molding layer 160 may cover the upper surface and side surfaces of the first support insulating layer 142. The molding layer 160 may be buried in the space (the area) between the first support insulating layer 142 on the second support dummy substrate 320 and the first support dummy substrate 150. That is, the molding layer 160 may fill the space (the area) between the first support dummy substrate 150 and the second support dummy substrate 320 and surround solder balls 158.

According to an embodiment, all of the solder balls 158 may be provided within edges of the upper surface of the second support dummy substrate 320, in a plan view.

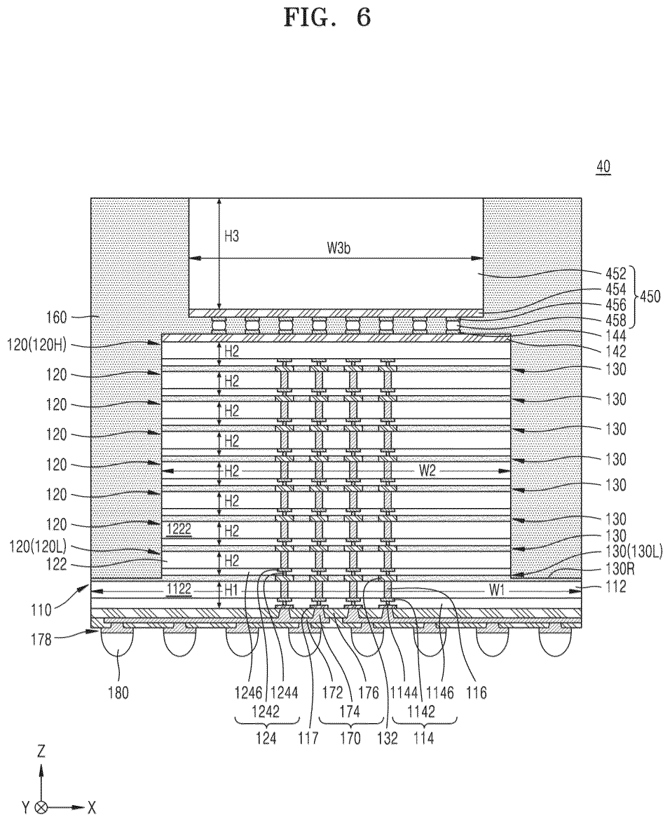

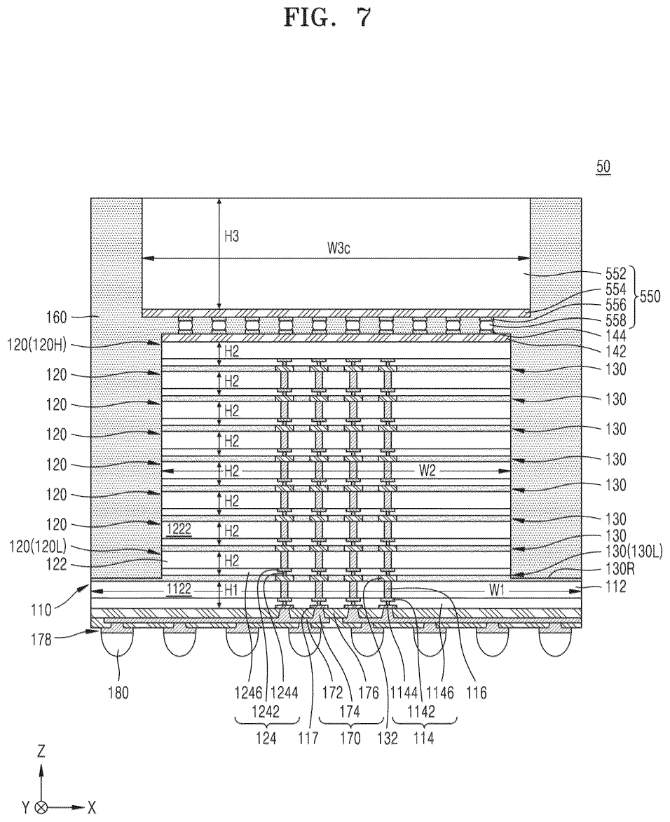

The semiconductor packages 40 and 50 respectively illustrated in FIGS. 6 and 7 may be substantially the same as or similar to the semiconductor package 10 illustrated in FIGS. 1 and 2, except that the horizontal widths of support dummy substrates 450 and 550 are different from that of the support dummy substrate 150 of FIGS. 1 and 2. Therefore, descriptions of the components already given above with reference to FIGS. 1 and 2 are omitted or briefly given.

Referring to FIG. 6, the semiconductor package 40 includes a first semiconductor chip 110 and a plurality of second semiconductor chips 120. The first semiconductor chip 110 and the plurality of second semiconductor chips 120 in the semiconductor package 40 may be electrically connected to each other through a plurality of coupling pads 132 to exchange signals and provide power and ground.

The first semiconductor chip 110 may have a first horizontal width W1 and a first vertical height H1 and each of the plurality of second semiconductor chips 120 may have a second horizontal width W2 and a second vertical height H2.

The support dummy substrate 450 may be stacked above or on the uppermost second semiconductor chip 120H. The support dummy substrate 450 may include, for example, a semiconductor material, such as silicon. In some embodiments, the support dummy substrate 450 may include only the semiconductor material. For example, the support dummy substrate 450 may include a portion of a bare wafer.

The support dummy substrate 450 may have a third horizontal width W3b and a third vertical height H3. The third vertical height H3 of the support dummy substrate 450 shown in FIG. 6 and the third vertical height H3 of the support dummy substrate 150 shown in FIG. 1 may be substantially equal to each other. However, the third horizontal width W3b of the support dummy substrate 150 shown in FIG. 6 is less than the third horizontal width W3a of the support dummy substrate 150 shown in FIG. 1. That is, the third horizontal width W3b of the support dummy substrate 450 is less than the second horizontal width W2 of the second semiconductor chip 120. Accordingly, the side surfaces of the support dummy substrate 450 may not be aligned with the side surfaces of the plurality of second semiconductor chips 120 in the vertical direction (Z direction).

The support dummy substrate 450 may include a first support insulating layer 142 disposed on the lower surface of the support dummy substrate 450, a plurality of connection pads 456 arranged on the lower surface of the first support insulating layer 142, and solder balls 458 respectively bonded to the plurality of connection pads 456. Here, the plurality of connection pads 456 and the plurality of solder balls 458 may be substantially the same as the plurality of connection pads 156 and the plurality of solder balls 158, respectively, shown in FIGS. 1 and 2. However, a second support insulating layer 454 extends along the lower surface of a body 452, and thus, the second support insulating layer 454 may have a horizontal width that is less than that of the second support insulating layer 154 shown in FIGS. 1 and 2.

Referring to FIG. 7, a support dummy substrate 550 of the semiconductor package 50 may have a third horizontal width W3c and a third vertical height H3. The third vertical height H3 of the support dummy substrate 550 shown in FIG. 7 and the third vertical height H3 of the support dummy substrate 150 shown in FIG. 1 may be substantially equal to each other. However, the third horizontal width W3c of the support dummy substrate 550 shown in FIG. 7 is greater than the third horizontal width W3a of the support dummy substrate 150 shown in FIG. 1. That is, the third horizontal width W3c of the support dummy substrate 550 is greater than the second horizontal width W2 of the second semiconductor chip 120. Accordingly, the side surfaces of the support dummy substrate 550 may not be aligned with the side surfaces of the plurality of second semiconductor chips 120 in the vertical direction (Z direction).

The support dummy substrate 550 may include a second support insulating layer 554 disposed on the lower surface of a body 552, a plurality of connection pads 556 arranged on the lower surface of the second support insulating layer 554, and solder balls 558 respectively bonded to the plurality of connection pads 556. Here, the plurality of connection pads 556 and the plurality of solder balls 558 may be substantially the same as the plurality of connection pads 156 and the plurality of solder balls 158, respectively, shown in FIGS. 1 and 2. However, the second support insulating layer 554 extends along the lower surface of the body 552, and thus, the second support insulating layer 554 may have a horizontal width that is greater than that of the second support insulating layer 154 shown in FIGS. 1 and 2.

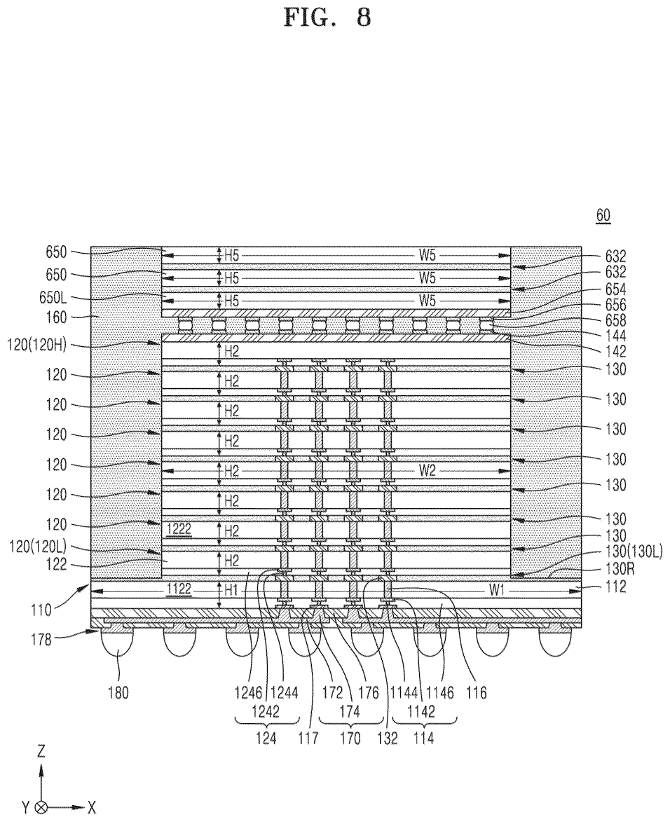

Referring to FIG. 8, the semiconductor package 60 includes a first semiconductor chip 110 and a plurality of second semiconductor chips 120. The first semiconductor chip 110 and the plurality of second semiconductor chips 120 in the semiconductor package 60 may be electrically connected to each other through a plurality of coupling pads 132 to exchange signals and provide power and ground.

The first semiconductor chip 110 may have a first horizontal width W1 and a first vertical height H1 and each of the plurality of second semiconductor chips 120 may have a second horizontal width W2 and a second vertical height H2.

A plurality of support dummy substrates 650 may be stacked above or on an uppermost second semiconductor chip 120H. The plurality of support dummy substrates 650 may include, for example, a semiconductor material, such as silicon. In some embodiments, the plurality of support dummy substrates 650 may include only the semiconductor material. For example, each of the plurality of support dummy substrates 650 may include a portion of a bare wafer. The total vertical height of the plurality of stacked support dummy substrates 650 may be greater than the second vertical height H2 of the second semiconductor chip 120. For example, the total vertical height of the plurality of stacked support dummy substrates 650 may be about 100 micrometers to about 500 micrometers.

Each of the plurality of support dummy substrates 650 may have a fifth horizontal width W5 and a fifth vertical height H5. In some embodiments, the fifth horizontal width W5 may be less than the first horizontal width W1 and equal to the second horizontal width W2. In some embodiments, the fifth vertical height H5 may be substantially equal to the first vertical height H1 and the second vertical height H2. For example, the fifth vertical height H5 may be about 50 micrometers to about 90 micrometers. In some embodiments, the fifth vertical height H5 may be less than the first vertical height H1 and the second vertical height H2. For example, the fifth vertical height H5 may be substantially equal to the vertical heights of the first semiconductor substrate 112 and the second semiconductor substrate 122 and may be less than the first vertical height H1 and the second vertical height H2 by several micrometers.

Substrate coupling insulating layers 632 may be respectively located between the plurality of support dummy substrates 650. The substrate coupling insulating layers 632 respectively located between the plurality of support dummy substrates 650 may not include the coupling pads 132 therein, unlike chip coupling insulating layers 130 located between the plurality of second semiconductor chips 120.

According to an embodiment, the semiconductor package 60 may include a second support insulating layer 654 disposed on the lower surface of a lowermost support dummy substrate 650L among the plurality of support dummy substrates 650, a plurality of connection pads 656 arranged on the lower surface of the second support insulating layer 654, and solder balls 658 respectively bonded to the plurality of connection pads 656. The second support insulating layer 654, the plurality of connection pads 656, and the plurality of solder balls 658 shown in FIG. 8 may be substantially the same as the second support insulating layer 154, the plurality of connection pads 156, and the plurality of solder balls 158 shown in FIG. 1.

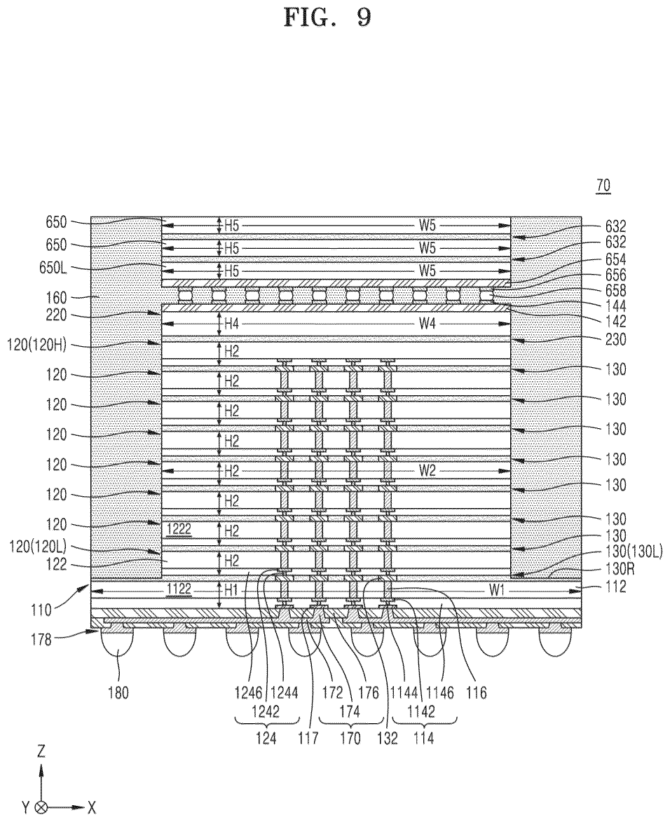

Referring to FIG. 9, the semiconductor package 70 may be substantially the same as or similar to the semiconductor package 60 illustrated in FIG. 8, except that the semiconductor package 70 further includes a second support dummy substrate 220. The second support dummy substrate 220 shown in FIG. 9 is substantially the same as the second support dummy substrate 320 of the semiconductor package 30 shown in FIG. 5.

According to an embodiment, the semiconductor package 70 may include the second support dummy substrate 220 stacked on a plurality of second semiconductor chips 120 stacked in a vertical direction (Z direction) and a plurality of first support dummy substrates 650 spaced apart from the second support dummy substrate 220 and stacked in the vertical direction (Z direction). Here, the second support insulating layer 654 extending along the lower surface of a first support dummy substrate 650 may be disposed on the lower surface of a lowermost first support dummy substrate 650L among the plurality of first support dummy substrates 650. Also, a plurality of connection pads 656 may be arranged on the second support insulating layer 654 in a first horizontal direction (X direction) or a second horizontal direction (Y direction) and solder balls 658 may be respectively attached to the plurality of connection pads 656. The plurality of solder balls 658 may be respectively bonded to a plurality of chip pads 144 formed on the second support dummy substrate 220 and may thus be arranged between the plurality of connection pads 656 and the plurality of chip pads 144.

FIGS. 10 to 17 are cross-sectional views sequentially showing a process of manufacturing a semiconductor package, according to an embodiment.

Referring to FIG. 10, a plurality of first chip connection pads 1321 and a first chip coupling insulating material layer 131 are formed on the upper surface of a first semiconductor chip 110. The plurality of first chip connection pads 1321 may be arranged on the upper surface, that is, the inactive surface, of the first semiconductor chip 110. The plurality of first chip connection pads 1321 may be disposed on the upper surface of the first semiconductor chip 110 so that the first chip connection pads 1321 are respectively connected to a plurality of first electrodes 116. The first chip coupling insulating material layer 131 may be formed on the upper surface, that is, the inactive surface, of the first semiconductor chip 110 and surround side surfaces of the plurality of first chip connection pads 1321. The first chip coupling insulating material layer 131 may cover the upper surface of the first semiconductor chip 110 and the side surfaces of the plurality of first chip connection pads 1321 but may expose the plurality of first chip connection pads 1321 without covering the upper surfaces of the first chip connection pads 1321.

The first semiconductor chip 110 having the plurality of first chip connection pads 1321 and the first chip coupling insulating material layer 131 formed on the upper surface thereof is attached on a first support substrate 1001. After a first release film 1002 is attached to the upper surface of the first support substrate 1001, the first semiconductor chip 110 may be attached on the first release film 1002. The first semiconductor chip 110 may be attached to the first release film 1002 such that a first wiring structure 114 faces the first support substrate 1001.

The plurality of first chip connection pads 1321 and the first chip coupling insulating material layer 131 are also formed on the upper surface of a second semiconductor chip 120. The plurality of first chip connection pads 1321 may be arranged on the upper surface, that is, the inactive surface, of the second semiconductor chip 120. The plurality of first chip connection pads 1321 may be disposed on the upper surface of the second semiconductor chip 120 so that the first chip connection pads 1321 are respectively connected to a plurality of second electrodes 126. The first chip coupling insulating material layer 131 may be formed on the upper surface, that is, the inactive surface, of the second semiconductor chip 120 and surround side surfaces of the plurality of first chip connection pads 1321. The first chip coupling insulating material layer 131 may cover the upper surface of the second semiconductor chip 120 and the side surfaces of the plurality of first chip connection pads 1321 but may expose the plurality of first chip connection pads 1321 without covering the upper surfaces of the first chip connection pads 1321.

A plurality of second chip connection pads 1322 and a second chip coupling insulating material layer 134 are formed on the lower surface of the second semiconductor chip 120. The plurality of second chip connection pads 1322 may be disposed on the lower surface of the second semiconductor chip 120, that is, the lower surface of a second wiring structure 124. The plurality of second chip connection pads 1322 may be disposed on the lower surface of the second semiconductor chip 120 so that the second chip connection pads 1322 are respectively connected to second wiring patterns 1242 and/or second wiring vias 1244. The second chip coupling insulating material layer 134 may be formed on the lower surface of the second semiconductor chip 120 and surround side surfaces of the plurality of second chip connection pads 1322. The second chip coupling insulating material layer 134 may cover the lower surface of the second semiconductor chip 120 and the side surfaces of the plurality of second chip connection pads 1322 but may expose the plurality of second chip connection pads 1322 without covering the lower surfaces of the second chip connection pads 1322.

The second semiconductor chip 120 is placed on the first semiconductor chip 110. The second semiconductor chip 120 may include the lowermost second semiconductor chip 120L shown in FIG. 1. The lowermost second semiconductor chip 120L may be positioned on the first semiconductor chip 110 such that the second wiring structure 124 of the lowermost second semiconductor chip 120L faces the first semiconductor chip 110. The lowermost second semiconductor chip 120L may be positioned on the first semiconductor chip 110 such that the plurality of second chip connection pads 1322 formed on the lowermost second semiconductor chip 120L respectively correspond to the plurality of first chip connection pads 1321 formed on the upper surface of the first semiconductor chip 110.

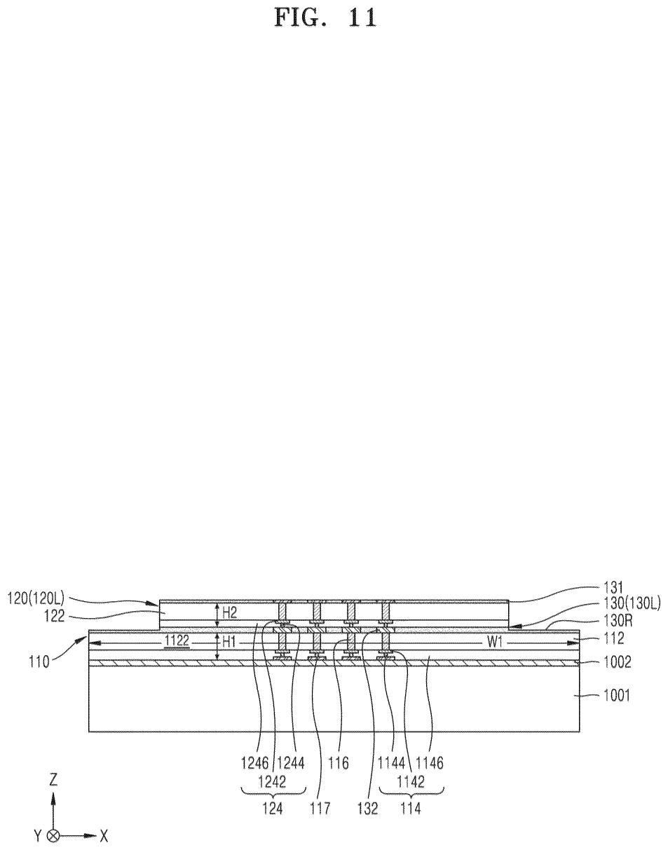

Referring to FIGS. 10 and 11, during the process of placing the lowermost second semiconductor chip 120L on the first semiconductor chip 110, heat and/or pressure is applied thereto. Accordingly, the plurality of first chip connection pads 1321 and the plurality of second chip connection pads 1322 may be bonded to each other and the first chip coupling insulating material layer 131 and the second chip coupling insulating material layer 134 may be bonded to each other. In embodiments, the plurality of first chip connection pads 1321 and the plurality of second chip connection pads 1322 may be bonded to each other by forming covalent bonds and the first chip coupling insulating material layer 131 and the second chip coupling insulating material layer 134 may be bonded to each other by forming covalent bonds. For example, during the process of placing the second semiconductor chip 120 on the first semiconductor chip 110, heat at a first temperature may be applied thereto.

Subsequently, heat at a second temperature higher than the first temperature is applied to the first semiconductor chip 110 and the second semiconductor chip 120. Accordingly, the plurality of coupling pads 132 may be formed by coupling the plurality of first chip connection pads 1321 and the plurality of corresponding second chip connection pads 1322 to each other and the chip coupling insulating layer 130 may be formed by coupling the first chip coupling insulating material layer 131 and the second chip coupling insulating material layer 134 to each other. The plurality of first chip connection pads 1321 and the plurality of corresponding second chip connection pads 1322 may be expanded by the heat and brought into contact with each other and then integrated with each other by diffusion of metal atoms contained therein. Accordingly, the plurality of coupling pads 132 may be formed through the diffusion bonding.

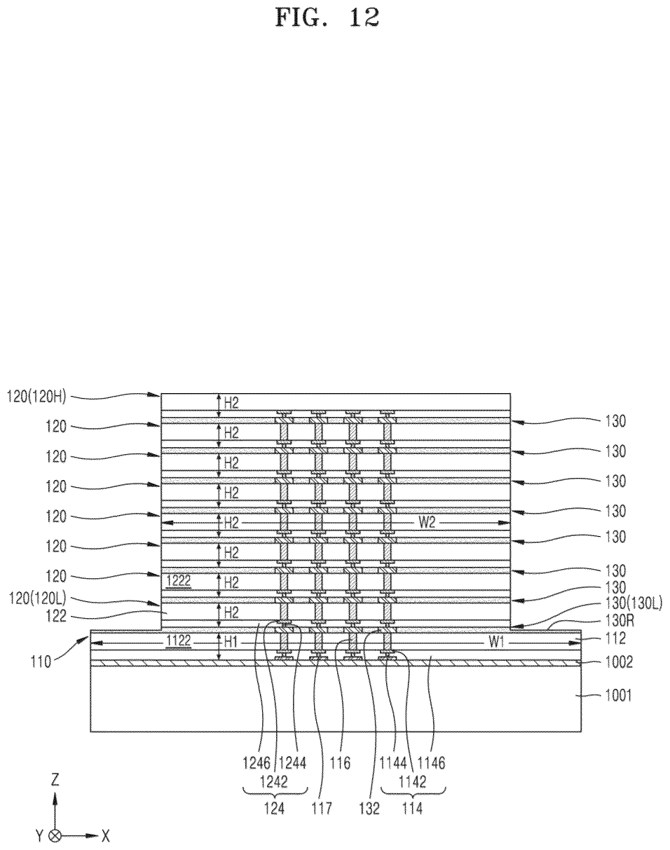

Referring to FIG. 12, a plurality of second semiconductor chips 120 are sequentially placed on the lowermost second semiconductor chip 120L. A plurality of second chip connection pads 1322 and a second chip coupling insulating material layer 134 are formed on the lower surfaces of the plurality of second semiconductor chips 120 that are sequentially placed on the lowermost second semiconductor chip 120L, and a plurality of first chip connection pads 1321 and a first chip coupling insulating material layer 131 may be formed on the upper surface of the second semiconductor chips 120, other than the uppermost second semiconductor chip 120H, among the plurality of second semiconductor chips 120.

Subsequently, a plurality of coupling pads 132, in which the plurality of first chip connection pads 1321 and the plurality of second chip connection pads 1322 are coupled to each other, and a chip coupling insulating layer 130, in which the first chip coupling insulating material layer 131 and the second chip coupling insulating material layer 134 are coupled to each other, may be formed between the plurality of second semiconductor chips 120 in a method similar to that described in FIG. 11. Accordingly, the plurality of second semiconductor chips 120 may be sequentially attached to the first semiconductor chip 110.

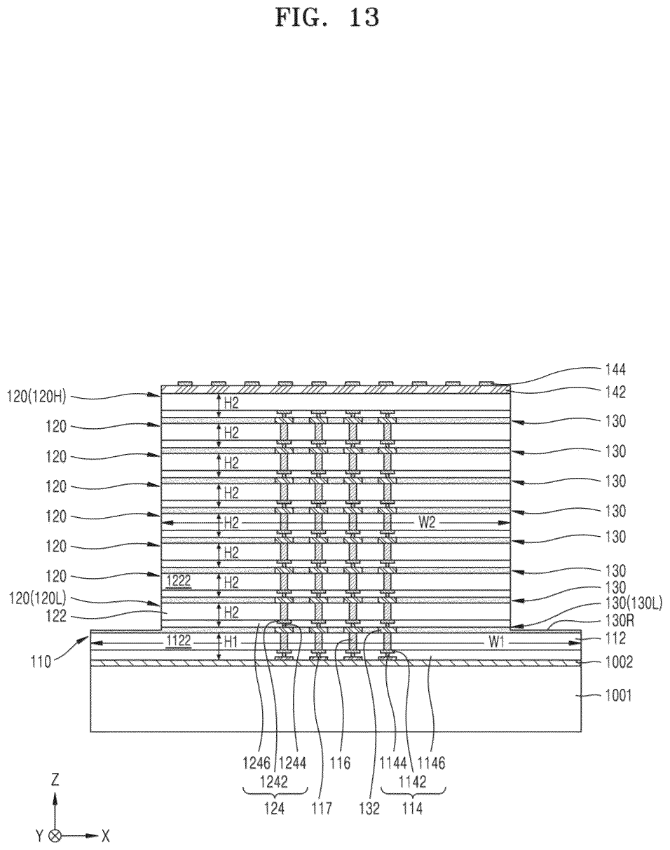

Referring to FIG. 13, a first support insulating layer 142 may be formed on the uppermost second semiconductor chip 120H. Here, the first support insulating layer 142 may be formed by depositing an insulating material containing silicon nitride on the upper surface of the uppermost second semiconductor chip 120H. The first support insulating layer 142 may completely and conformally cover the upper surface of the uppermost second semiconductor chip 120H. Subsequently, a plurality of chip pads 144 may be formed on the upper surface of the first support insulating layer 142 through a plating process.

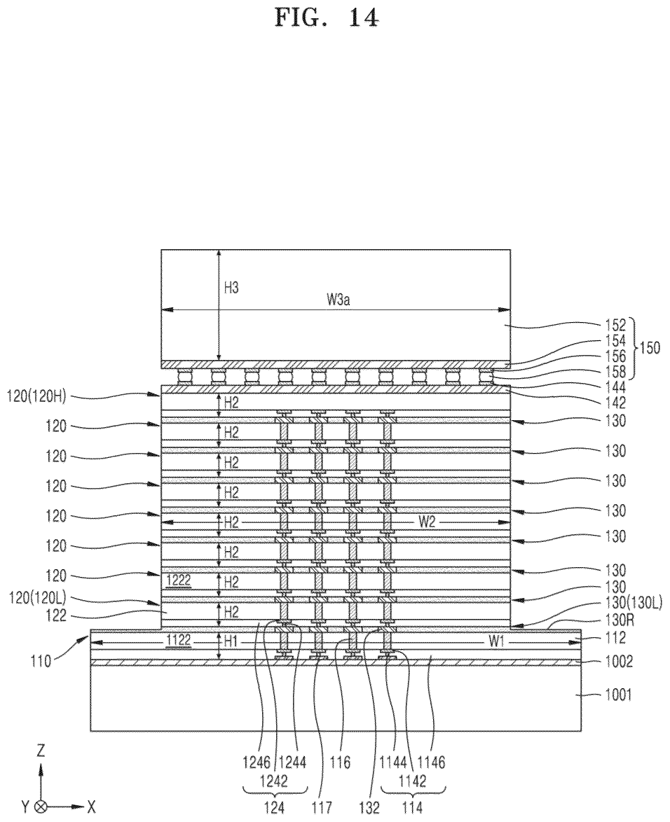

Referring to FIG. 14, a support dummy substrate 150 may be mounted on the first support insulating layer 142. The support dummy substrate 150 may include a body 152, a second support insulating layer 154, a plurality of connection pads 156, and a plurality of solder balls 158. The second support insulating layer 154 may conformally cover the lower surface of the body 152, and the plurality of connection pads 156 may be arranged on the lower surface of the second support insulating layer 154 in a first horizontal direction (X direction) or a second horizontal direction (Y direction). The support dummy substrate 150 may be mounted on the first support insulating layer 142 so as to completely overlap the plurality of stacked second semiconductor chips 120 in a vertical direction (Z direction). The plurality of solder balls 158 may be respectively bonded to the plurality of chip pads 144. According to an embodiment, the plurality of solder balls 158 may be used in a self-alignment manner between the plurality of connection pads 156 and the plurality of chip pads 144. The plurality of solder balls 158 in a molten state may be bonded to the plurality of chip pads 144. During a solidification process, the molten solder balls 158 may be self-aligned due to the surface tension of the solder balls 158.

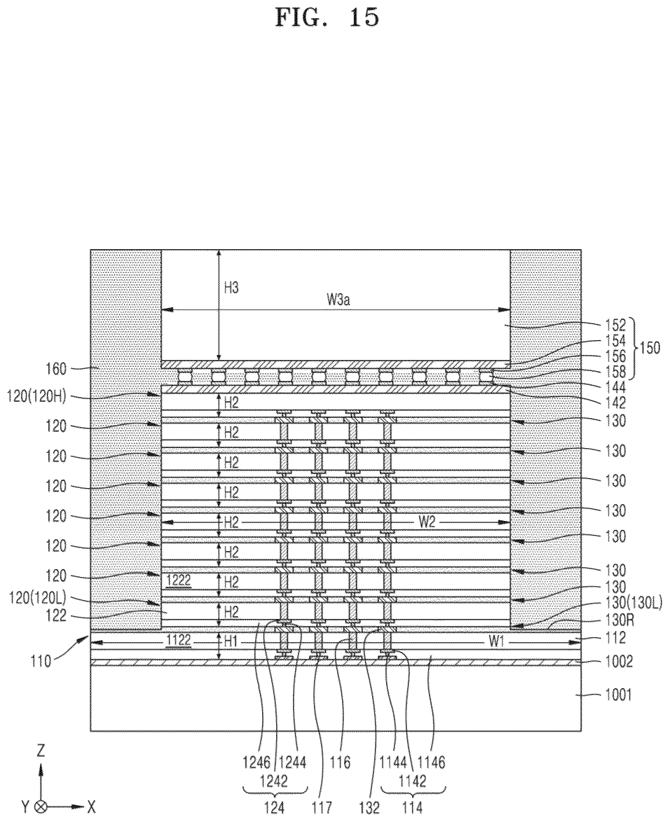

Referring to FIG. 15, a molding layer 160 may be formed on the first semiconductor chip 110. The molding layer 160 may cover the upper surface of the first semiconductor chip 110 and surround the side surfaces of the plurality of second semiconductor chips 120 and the support dummy substrate 150. After the molding layer 160 is formed, the first support substrate 1001, to which the first release film 1002 is attached, may be separated from the first semiconductor chip 110.

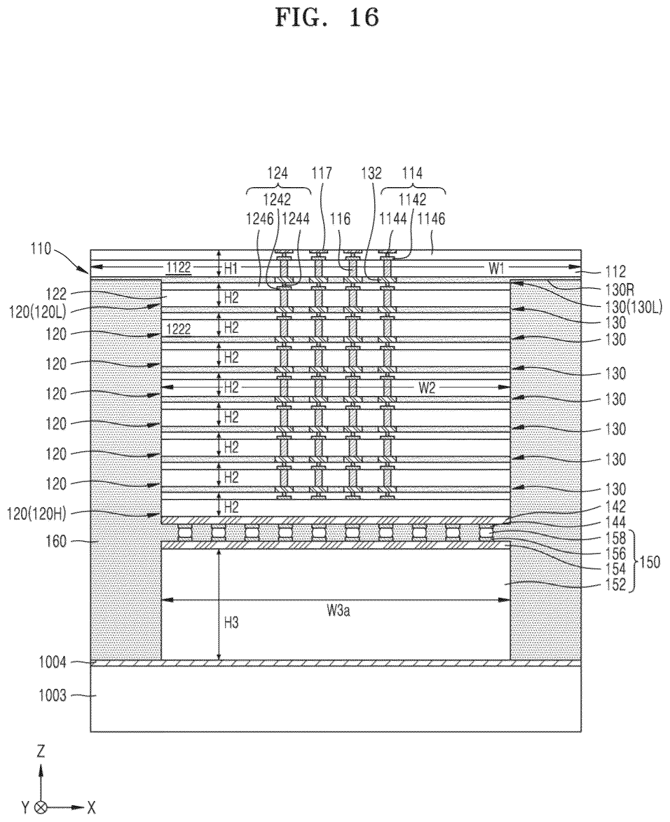

Referring to FIG. 16, the result of FIG. 15 is turned over and attached to a second support substrate 1003. A second release film 1004 may be attached to the upper surface of the second support substrate 1003, and then the flipped result shown in FIG. 16 may be attached to the second release film 1004. The support dummy substrate 150 and the molding layer 160 may be in contact with the second release film 1004.

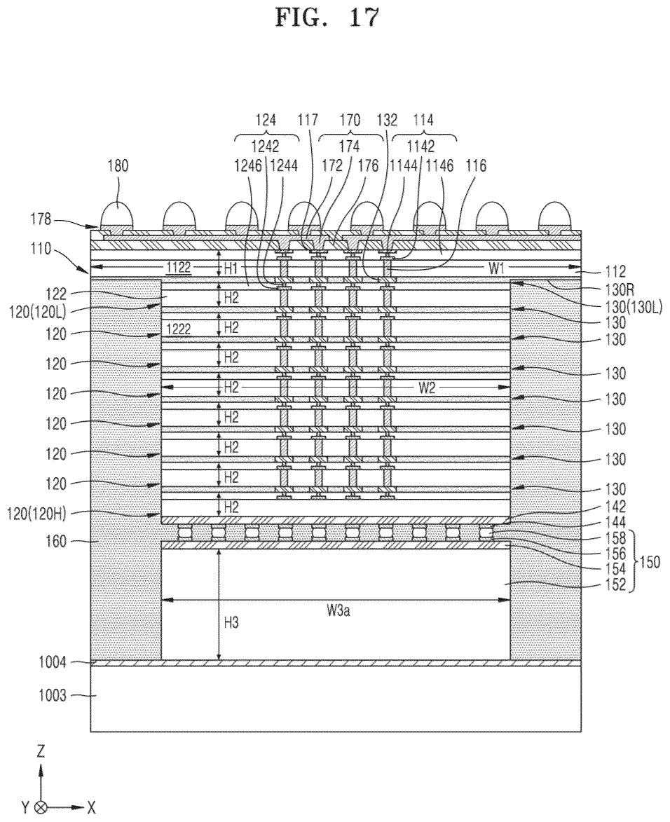

Referring to FIG. 17, a base redistribution layer 170 is formed on the first wiring structure 114 of the first semiconductor chip 110. The base redistribution layer 170 may include a plurality of package redistribution line patterns 172, a plurality of package redistribution vias 174, and a package redistribution insulating layer 176. At least some of the plurality of package redistribution vias 174 or at least some of the plurality of package redistribution line patterns 172 may be in contact with a plurality of lower chip pads 117. A package redistribution line pattern 172, which is disposed on the upper surface of the base redistribution layer 170, among the plurality of package redistribution line patterns 172 may be referred to as a package pad 178. In some embodiments, the plurality of package redistribution vias 174 may each have a tapered shape extending from the bottom to the top with an increasing horizontal width. That is, the horizontal width of each of the plurality of package redistribution vias 174 may increase in a direction away from the first semiconductor chip 110. Subsequently, a plurality of package connection terminals 180 may be respectively attached to a plurality of package pads 178. Then, the second support substrate 1003, to which the second release film 1004 is attached, is separated from the support dummy substrate 150 and the molding layer 160. When the result is turned over, the semiconductor package 10 shown in FIG. 1 may be formed.

While certain embodiments of the disclosure have been particularly shown and described, it will be understood that various changes in form and details may be made therein without departing from the spirit and scope of the following claims.

What is claimed is:

1. A semiconductor package comprising:
a first semiconductor chip comprising:
a first semiconductor substrate having an first active surface and a first inactive surface opposite to the first active surface, and
a plurality of first electrodes penetrating through the first semiconductor substrate;
a plurality of second semiconductor chips, each of the plurality of second semiconductor chips comprising:
a second semiconductor substrate having a second active surface and a second inactive surface opposite to the second active surface, and
a plurality of second electrodes penetrating through the second semiconductor substrate and stacked on the first semiconductor chip, wherein the second active surfaces of the plurality of second semiconductor substrates face the first inactive surface of the first semiconductor substrate, and the plurality of second semiconductor chips have vertical heights that are equal to each other;
a plurality of coupling pads between the first semiconductor chip and the plurality of second semiconductor chips, the plurality of coupling pads electrically connecting the plurality of first electrodes to the plurality of second electrodes;
chip coupling insulating layers, each of the chip coupling insulating layers surrounding the plurality of coupling pads and provided between the first semiconductor chip and the plurality of second semiconductor chips; and
a support dummy substrate stacked on the plurality of second semiconductor chips, the support dummy substrate comprising a first support insulating layer on a lower surface of the support dummy substrate,
wherein an uppermost second semiconductor chip among the plurality of second semiconductor chips comprises a plurality of chip pads on the second inactive surface of the second semiconductor substrate of the uppermost second semiconductor chip, and
wherein the support dummy substrate comprises a plurality of solder balls on the lower surface of the support dummy substrate, and the plurality of solder balls are bonded to the plurality of chip pads.

2. The semiconductor package of claim 1, wherein a vertical height of the support dummy substrate is greater than a vertical height of the first semiconductor chip and the vertical heights of the plurality of second semiconductor chips.

3. The semiconductor package of claim 1, wherein a horizontal length of the support dummy substrate is less than a horizontal length of each of the plurality of second semiconductor chips.

4. The semiconductor package of claim 1, wherein a horizontal length of the support dummy substrate is longer than a horizontal length of each of the plurality of second semiconductor chips.

5. The semiconductor package of claim 1, wherein the plurality of coupling pads and at least one of the chip coupling insulating layers are bonded together through diffusion bonding.

6. The semiconductor package of claim 1, wherein the at least one of the chip coupling insulating layers covers an upper surface of the first semiconductor chip, and
wherein a thickness of a first portion of the at least one of the chip coupling insulating layers, which overlaps the plurality of second semiconductor chips in a vertical direction, is greater than a thickness of a second portion of the at least one of the chip coupling insulating layers, which does not overlap the plurality of second semiconductor chips in the vertical direction.

7. The semiconductor package of claim 1, wherein a side surface of each of the plurality of second semiconductor chips is aligned with a side surface of the support dummy substrate in a vertical direction.

8. The semiconductor package of claim 1, further comprising a molding layer provided on the first semiconductor chip,
wherein the molding layer covers an upper surface of the first semiconductor chip, side surfaces of the plurality of second semiconductor chips, and the lower surface and side surfaces of the support dummy substrate, and
wherein the molding layer exposes an upper surface of the support dummy substrate without covering the upper surface of the support dummy substrate.

9. The semiconductor package of claim 8, wherein the molding layer fills an area between the support dummy substrate and the uppermost second semiconductor chip among the plurality of second semiconductor chips, and
wherein the molding layer encloses the plurality of solder balls.

10. The semiconductor package of claim 1, wherein the uppermost second semiconductor chip is spaced apart from the support dummy substrate in a vertical direction.

11. A semiconductor package comprising:
a high bandwidth memory (HBM) controller die comprising:
a first semiconductor substrate having a first active surface and a first inactive surface opposite to the first active surface, and
a plurality of first electrodes at least partially penetrating through the first semiconductor substrate;
a plurality of dynamic random access memory (DRAM) dies, each of the plurality of DRAM dies comprising:
a second semiconductor substrate having a second active surface and a second inactive surface opposite to the second active surface, and
a plurality of second electrodes penetrating through the second semiconductor substrate and stacked on the HBM controller die, wherein the second active surfaces of the plurality of second semiconductor substrates face the first inactive surface of the first semiconductor substrate, and the plurality of DRAM dies have vertical heights that are equal to each other;
a plurality of coupling pads between the HBM controller die and the plurality of DRAM dies, the plurality of coupling pads electrically connecting the plurality of first electrodes to the plurality of second electrodes;
chip coupling insulating layers, each of the chip coupling insulating layers surrounding the plurality of coupling pads and provided between the HBM controller die and the plurality of DRAM dies;
at least one first support dummy substrate stacked on the plurality of DRAM dies; and
a second support dummy substrate between the at least one first support dummy substrate and an uppermost DRAM die among the plurality of DRAM dies,
wherein the second support dummy substrate comprises a plurality of chip pads on an upper surface of the second support dummy substrate that faces the at least one first support dummy substrate, and
wherein the at least one first support dummy substrate comprises a plurality of solder balls on a lower surface of the at least one first support dummy substrate that faces the second support dummy substrate, and the plurality of solder balls are bonded to the plurality of chip pads.

12. The semiconductor package of claim 11, wherein a vertical height of the second support dummy substrate is equal to the vertical heights of the plurality of DRAM dies.

13. The semiconductor package of claim 11, further comprising a molding layer provided on the HBM controller die,
wherein the molding layer covers an upper surface of the HBM controller die, side surfaces of the plurality of DRAM dies, side surfaces of the second support dummy substrate, and the lower surface and side surfaces of the at least one first support dummy substrate, and
wherein the molding layer exposes an upper surface of the at least one first support dummy substrate without covering the upper surface of the at least one first support dummy substrate.

14. The semiconductor package of claim 13, wherein the molding layer fills an area between the at least one first support dummy substrate and the second support dummy substrate, and
wherein the molding layer encloses the plurality of solder balls.

15. The semiconductor package of claim 11, wherein a horizontal length of the second support dummy substrate is equal to the horizontal lengths of the plurality of DRAM dies.

16. The semiconductor package of claim 11, wherein the plurality of solder balls are provided within edges of the upper surface of the second support dummy substrate, in a plan view.

17. The semiconductor package of claim 11, wherein the at least one first support dummy substrate corresponds to a plurality of first support dummy substrates that are stacked on the plurality of DRAM dies, and
wherein a vertical height of at least one of the plurality of first support dummy substrates is less than or equal to a vertical height of the HBM controller die and the vertical heights of the plurality of DRAM dies.

18. A semiconductor package comprising:
a base redistribution layer comprising:
a plurality of package redistribution line patterns,
a plurality of package redistribution vias contacting and connected to at least one of the plurality of package redistribution line patterns, and
a package redistribution insulating layer surrounding the plurality of package redistribution line patterns and the plurality of package redistribution vias;
a high bandwidth memory (HBM) controller die comprising:
a first semiconductor substrate having a first active surface and a first inactive surface opposite to the first active surface, and
a plurality of first electrodes at least partially penetrating through the first semiconductor substrate, wherein the HBM controller die has a first horizontal width and a first vertical height;
a plurality of dynamic random access memory (DRAM) dies, each of the plurality of DRAM dies comprising a second semiconductor substrate having a second active surface and a second inactive surface opposite to the second active surface, wherein the plurality of DRAM dies are stacked on the HBM controller die, the second active surfaces of the plurality of second semiconductor substrates face the first inactive surface of the first semiconductor substrate, and each of the plurality of DRAM dies has a second horizontal width that is less than the first horizontal width of the HBM controller die and a second vertical height;
a plurality of coupling pads between the HBM controller die and the plurality of DRAM dies;
chip coupling insulating layers, each of the chip coupling insulating layers surrounding the plurality of coupling pads and provided between the HBM controller die and the plurality of DRAM dies;
a support dummy substrate on the plurality of DRAM dies, the support dummy substrate having a third horizontal width that is equal to the second horizontal width of at least one DRAM die of the plurality of DRAM dies and a third vertical height that is greater than the first vertical height of the HBM controller die and the second vertical height of the at least one DRAM die of the plurality of DRAM dies;
a support coupling insulating layer on an inactive surface of an uppermost DRAM die among the plurality of DRAM dies;
a plurality of chip pads on a surface of the support coupling insulating layer that faces the support dummy substrate; and
a molding layer provided on the HBM controller die, the molding layer covering an upper surface of the HBM controller die, side surfaces and an upper surface of the plurality of DRAM dies, and side surfaces and a lower surface of the support dummy substrate, wherein the molding layer exposes an upper surface of the support dummy substrate without covering the upper surface of the support dummy substrate,
wherein the support dummy substrate comprises a plurality of solder balls on the lower surface of the support dummy substrate that faces the upper surface of the support coupling insulating layer, and the plurality of solder balls are bonded to the plurality of chip pads.

19. The semiconductor package of claim 18, wherein the third vertical height of the support dummy substrate is about 100 micrometers to about 500 micrometers.

20. The semiconductor package of claim 18, wherein the plurality of coupling pads comprise a material containing Cu,
wherein the chip coupling insulating layers comprise silicon oxide, and
wherein the support coupling insulating layer comprises silicon nitride.
